(19) United States
(12) Patent Application Publication
(10) Pub. No.: US 2009/0035939 A1
(43) Pub. Date: Feb. 5, 2009

(54) FABRICATION METHOD TO MINIMIZE BALLAST LAYER DEFECTS

(75) Inventors: Steven Young, Gilbert, AZ (US); William Dauksher, Mesa, AZ (US); Emmett Howard, Gilbert, AZ (US); Donald Weston, Phoenix, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/830,985

(22) Filed: Jul. 31, 2007

(51) Int. Cl. H01L 21/44

(52) U.S. Cl. 438/669; 257/E21.476

(57) ABSTRACT

A method for minimizing fabrication defects in ballast contact to a conductor in monolithically integrated semiconductor devices includes forming a sloping sidewall (318, 424) in both an insulating layer (106, 718) overlying a conductive layer (104, 714) by etching with a an RF biased fluorine based chemistry and an RF biased chlorine based chemistry, respectively, as defined by a single resist layer (108) having a sloped sidewall (212). A ballast layer (526, 726) is deposited on the structure (100, 700) and metal contacts (632, 634, 636, 638, 722) are disposed on the ballast layer (526, 722).

### FIELD

The present invention generally relates to electronic devices and more particularly to a method for minimizing fabrication defects in ballast contact to a conductor in monolithically integrated semiconductor devices.

### BACKGROUND

The fabrication of integrated circuits, microelectronic devices, micro electro mechanical devices, microfluidic devices, and photonic devices, involves the creation of several layers of materials that interact in some fashion. One or more of these layers may be patterned so various regions of the layer have different electrical characteristics, which may be interconnected within the layer or to other layers to create electrical components and circuits. These regions may be created by selectively introducing or removing various materials. The patterns that define such regions are often created by lithographic processes.

Contact between different layers typically is accomplished by forming vias, or metal channels, between the layers. Contact along sidewalls has also been accomplished by forming a conductor along the sidewall and between the metal layers. Both of these known processes require multiple lithographic steps and results in defects at the interface between the metal layer and a ballast layer. Defects of this type can create leakage paths between the layers which reduce device efficiency. In the most severe case, defects can become shorts between layers which prevent the device from functioning.

Accordingly, it is desirable to provide a method for method for minimizing fabrication defects in ballast contact to a conductor in monolithically integrated semiconductor devices. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIGS. 1-6 are partial cross-sections of the structure of an exemplary embodiment;

FIG. 7 is a partial cross-section of a field emission device cathode of another exemplary embodiment;

FIG. 8 is a partial perspective view of the exemplary embodiment of FIG. 1; and

FIG. 9 is a flow chart of the method according to the exemplary embodiment of FIGS. 7 and 8.

### DETAILED DESCRIPTION

A method is described that produces a ballast structure with minimal contact area to a highly conductive layer without the use of vias. A blanket insulating layer is formed over a blanket highly conductive layer. A resist layer, e.g., photoresist, is patterned over the insulating layer using a proximity mask to provide sloped sidewalls. A high RF bias dielectric etch using fluorine chemistry partially etches the resist layer and the insulating layer. Then a high RF bias metal etch using chlorine chemistry partially etches the resist layer, the insulating layer, and the conductive layer. A blanket ballast layer is formed over the structure. Then metal contacts are formed on the ballast layer for providing varying resistances from the metal contacts through the ballast layer to the conductive layer.

The following detailed description is merely exemplary in nature and is not intended to limit the invention or the application and uses of the invention. Furthermore, there is no intention to be bound by any theory presented in the preceding background or the following detailed description.

The exemplary embodiments described herein may be fabricated using known lithographic processes as follows. The fabrication of integrated circuits, microelectronic devices, micro electro mechanical devices, microfluidic devices, and photonic devices involves the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes. For example, a layer of photoresist material is applied onto a layer overlying a wafer substrate. A photomask (containing clear and opaque areas) is used to selectively expose this photoresist material by a form of radiation, such as ultraviolet light, electrons, or x-rays. Either the photoresist material exposed to the radiation, or that not exposed to the radiation, is removed by the application of a developer. An etch may then be applied to the layer not protected by the remaining resist, and when the resist is removed, the layer overlying the substrate is patterned. Alternatively, an additive process could also be used, e.g., building a structure using the photoresist as a template.

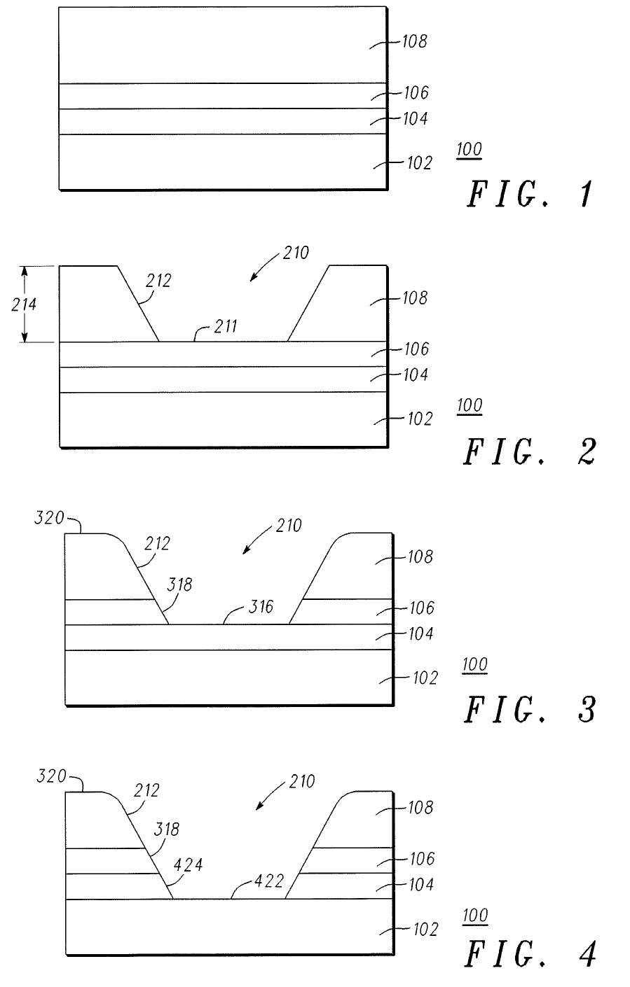

Referring to FIGS. 1-6, and in accordance with an exemplary embodiment, the monolithically integrated structure 100 includes a substrate 102, a conductive layer 104, a insulator layer 106, and a resist layer 108, e.g., photoresist. The layers 104, 106, 108 are formed using standard lithographic or deposition techniques. The substrate 102 is preferably silicon, but may be any known material, for example, semiconductor or insulating material including glass or polymer and can be either rigid or flexible. The conductive layer 104 preferably is a metal, for example, aluminum, tungsten, or molybdenum. The insulator layer 106 preferably is a dielectric material, for example, an oxide or nitride. The resist layer 108 preferably is based on a positive or negative toned resist that can be patterned using radiant energy, but may comprise any known in the industry.

The resist layer 108 is patterned (FIG. 2) using a proximity process or an out of focus stepper process, including the removal of a portion of the resist layer 108 to create an opening 210 to a surface 211 defined by the sloped sidewall 212 of the remaining resist layer 108. The sidewall 212 comprises a preferred angle in the range of 30 to 75 degrees, and a more preferred angle of 45 degrees (e.g., 1:1 selectivity), to the insulating layer 106. The thickness 214 of the resist layer 108 should be such that it gives sufficient protection during subsequent etching (discussed below) while transferring the slope to the etched conductive layer 104 and insulator layer 106.

A two step plasma etch processes is used to create tapered profiles in the insulator layer 106 and the conductive layer 104. The first step is a high RF bias dielectric etch using fluorine chemistry. The RF bias is applied to the substrate 102 and the fluorine chemistry is introduced to the structure 100 (FIG. 3) to remove a portion of the insulator layer 106 within the opening 210, thereby exposing a surface 316 of the conductive layer 104 and a sidewall 318 of the insulator layer 106. The sidewall 318 comprises an angle to the conductive layer 104 similar to the angle between the sidewall 212 and the insulating layer 106. This first step etch will also remove a portion of the resist layer 108, both on the sidewall 212 and on the surface 320. The resist layer 108 thickness, slope, and etch selectivity to the insulator layer 106 should be optimized to achieve the desired tapered profile.

The second step plasma etch process is a high RF bias metal etch using chlorine chemistry. The RF bias is applied to the substrate 102 and the chlorine chemistry is introduced to the structure 100 (FIG. 4) to remove a portion of the conductive layer 104 within the opening 210, thereby exposing a surface 422 of the substrate 102 and a sidewall 424 of the conductive layer 104. The sidewall 424 comprises an angle to the substrate 102 similar to the angle between the sidewall 318 and the conductive layer 104. Therefore, the sidewalls 318 and 424 substantially form a plane in line with and as determined by the sidewall 212. This second step etch will also remove a further portion of the resist layer 108, both on the sidewall 212 and on the surface 320 as well as remove a portion of the insulator layer 106 on sidewall 318. The resist layer 108 and insulator layer 106 thicknesses and etch selectivities to the conductive layer 104 should be optimized to achieve the desired final tapered profile. Reactive ion etch conditions in the second step are selected to provide a 1:1 etch rate selectivity between the insulator layer 106 and the conductive layer 104. The etch selectivity and slope of the resist defines the slope of the insulator layer 106 which in turn defines the slope of the conductive layer 104 if the etch rate selectivity is optimized at 1:1.

Referring to FIG. 5, the remaining resist layer 108 is removed by known etching methods, and a ballast layer 526 is formed, preferably by blanket deposition, over the insulator layer 106 and within the opening 210 including over the sidewalls 318, 424 of the insulator layer 106 and the conductive layer 104, respectively, and the surface 422 of the substrate 102. Then a conductive layer 528 is formed, preferably by blanket deposition, over the ballast layer 526, and patterned (FIG. 6) by known lithographic methods to create conductor 632 formed on the surface 642 of the ballast layer 526, conductor 634 formed on the surface 644 of the ballast layer 526, and conductors 636, 638 formed on the surface 646 of the ballast layer 526. The placement of these conductors 632, 634, 636, 638 is only by way of example. Such conductors may be positioned anywhere on the ballast layer 626, including on the sidewall 648.

It may be seen that the distances 652, 654, 656, 658 between each of the conductors 632, 634, 636, 638, respectively, and the conductive layer 104 through the ballast layer 526 will be different due to their placement, resulting in a different resistance for each of the conductors 632, 634, 636, 638.

This use of a sloped resist profile to transfer a tapered profile directly into a dielectric and conductive layers by a subsequent reactive ion etch step may be used in the fabrication of many types of electronic devices including any device with conductive contacts such as field emitters, resistors, transistors, capacitors, and diodes. One particular exemplary embodiment is that of a field emission display structure.

Field emission displays include an anode and a cathode structure. The cathode is configured into a matrix of rows and columns, such that a given pixel can be individually addressed. Addressing is accomplished by placing a positive voltage on one row at a time. During the row activation time, data is sent in parallel to each pixel in the selected row by way of a negative voltage applied to the column connections, while the anode is held at a high positive voltage. The voltage differential between the addressed cathode pixels and the anode accelerates the electrons emitted from the pixels toward the anode.

Field effect devices typically comprise a metal cathode on a substrate, with carbon nanotubes grown on the cathode. A metal catalyst may be positioned between the cathode and the carbon nanotubes for facilitating carbon nanotube growth. A gate electrode is positioned between an anode and the tops of the carbon nanotubes for controlling electron emission from the carbon nanotubes. Electrons flow from the metal cathode through the metal catalyst if present, and out the carbon nanotubes to the anode spaced therefrom.

Color field emission display devices typically include a cathodoluminescent material underlying an electrically conductive anode. The anode resides on an optically transparent frontplate and is positioned in parallel relationship to an electrically conductive cathode. The cathode is typically attached to a glass backplate and a two dimensional array of field emission sites is disposed on the cathode. The anode is divided into a plurality of pixels and each pixel is divided into three subpixels. Each subpixel is formed by a phosphor corresponding to a different one of the three primary colors, for example, red, green, and blue. Correspondingly, the electron emission sites on the cathode are grouped into pixels and subpixels, where each emitter subpixel is aligned with a red, green, or blue subpixel on the anode. By individually activating each subpixel, the resulting color can be varied anywhere within the color gamut triangle. The color gamut triangle is a standardized triangular-shaped chart used in the color display industry. The color gamut triangle is defined by each individual phosphor's color coordinates, and shows the color obtained by activating each primary color to a given output intensity.

However, vacuum field emission devices are commonly plagued with electrons being emitted (a leakage current) from various types of unintended emission sites. These spurious emission sites are often formed as an unintended consequence of the fabrication process. Unintended emitters can result, for example, from anomalously sharp edges of metal electrodes, conductive particles in high field regions, patterning defects, lifting metal, emitters (such as nanotubes) deposited in the wrong place, dielectric in unintended locations, dielectric with sharp edges and/or high aspect ratio geometries in the dielectric, etc. In addition, many types of field emission cathode structures have a gate electrode stack. This feature typically incorporates a metal gate electrode deposited on top of an insulator, which has been deposited on or very near a cathode electrode.

In the case where the anode field alone is sufficient to initiate electron emission, this undesired emission site is commonly referred to as an anode leader. The intensity of electron emission increases with the applied anode voltage. Furthermore, when field emission devices are in their ‘off’ state, the gate electrode potential is driven lower than the cathode electrode potential, creating a reverse bias condition. In this case, the cathode electrode itself provides the field which pulls electrons off the gate metal asperity. This emission site is often called a reverse bias leader. Both cases lead to image defects wherein the sub-pixels are always illuminated, resulting in loss of contrast and brightness, and the inability to operate the device at optimal conditions.

Another type of unintended emission results from defects at the edge of the gate electrode stack. Conductive particles can be defects at the base of the gate electrode stack. They might result from particles encountered in the process environment patterning defects re-deposited material during wet processing, or emitter features (such as nanotubes) erroneously deposited in the wrong place. The base of the gate electrode stack forms a junction between a conductor, an insulator, and vacuum which is commonly termed a triple point. This junction creates an enhanced electric field at the conductive defect, and under the influence of the gate potential and/or the anode potential, the conductive defect can emit electrons. These electrons typically cascade up the insulator sidewall, producing an unwanted leakage current between the anode and the cathode, and often produce emitted electrons at the anode. These defects typically are not ballasted by series resistance in the field emission structure so they contribute to excessive (and non-uniform) light at the sub-pixel. They also become hot and produce a run-away current condition that ends in the explosion of the defect, and sometimes a device shorting defect.

Previously known field emission structures, e.g., Spindt tip and some carbon nanotube emitters, often have an unpatterned oxide layer. These structures, comprising metal (cathode)-ballast-oxide-metal (gate), are fabricated by patterning only the top metal layer, leaving an exposed surface of dielectric (oxide). In fact, the manufacturing method of the Spindt tip specifically leaves this dielectric on the surface. This dielectric charges and produces arcs unless a bleed layer is applied to the top surface. To preserve a desired small number of masks, the catalyst or emitter is fabricated with a lift-off process. First, the lift-off photo layer is used as a mask (or to define a lift-off mask) which is used to etch through the oxide layer down to the underlying layers. Next, the emitter or catalyst material is deposited through the same lift-off masking layer into the well and onto the lift-off layer. Removal of the lift-off layer leaves patterned emitter or catalyst in three mask steps. However, the lift-off process does not scale to large size panels. A subtractive etch of the catalyst will be needed. Because these prior art methods use the lift off layer for both local oxide etch (via to bottom metal layer), they need a fourth mask to implement a subtractive etch. This is but one method to pattern the gate dielectric. Another method is to use the gate metal photo resist to etch both the gate metal and gate dielectric. This exposes the ballast layer where the catalyst can then be deposited patterned by resist and then subtractively etched. The number of mask steps remains unchanged from the liftoff method

Other methods may comprise a process with only three masks; however, there is a metal (cathode)-ballast-oxide-metal (gate) interface outside the emitter well that is susceptible to small defects resulting in arcs which may short out the device due in part to the ballast providing insufficient vertical resistance for suppressing any arcing. The bottom interface is effectively a metal-oxide-vacuum triple junction which is known to be susceptible to arcing.

Accordingly, it is desirable to provide a field emission device structure that prevents electrical breakdown with as few mask layers as possible.

In order to eliminate electron emission from residual conductive material on the insulator surface at the edge of the gate metal stack and other defects occurring at the edge of the gate metal stack, of a field emission display, a resistive layer acts as a lateral resistor for arc suppression. The resistive layer may be the same as a ballast layer that is used to couple the electron emitters to the cathode metal. A metal-oxide-ballast-oxide-metal stack is fabricated having the first metal with a sloped sidewall contacting the resistive layer. The first metal-oxide stack is patterned in one step with a slope on both layers, requiring no additional masks. The resistive layer also acts as a bleed layer for charges that accumulate on the cathode surface from operation of the device. Electrons and ions generated from operation of the device tend to collect on the cathode surface. Thus, it is important that either a metal layer or a resistive charge bleed layer cover all non-vertical surfaces of the cathode. Current design and technology does not allow for this feature. Previously known spacers must cross over the column lines, which would short columns together if contact were made. Because of the X and Y grid of cathode and gate lines, the spacer would short either cathode lines or gate lines. Traditional gate lines create spacer landing pads and used the gate metal to keep spacer potential equal to gate potential, with the gate dielectric being used to isolate the spacer from, and prevent the shorting of columns to, adjacent columns.

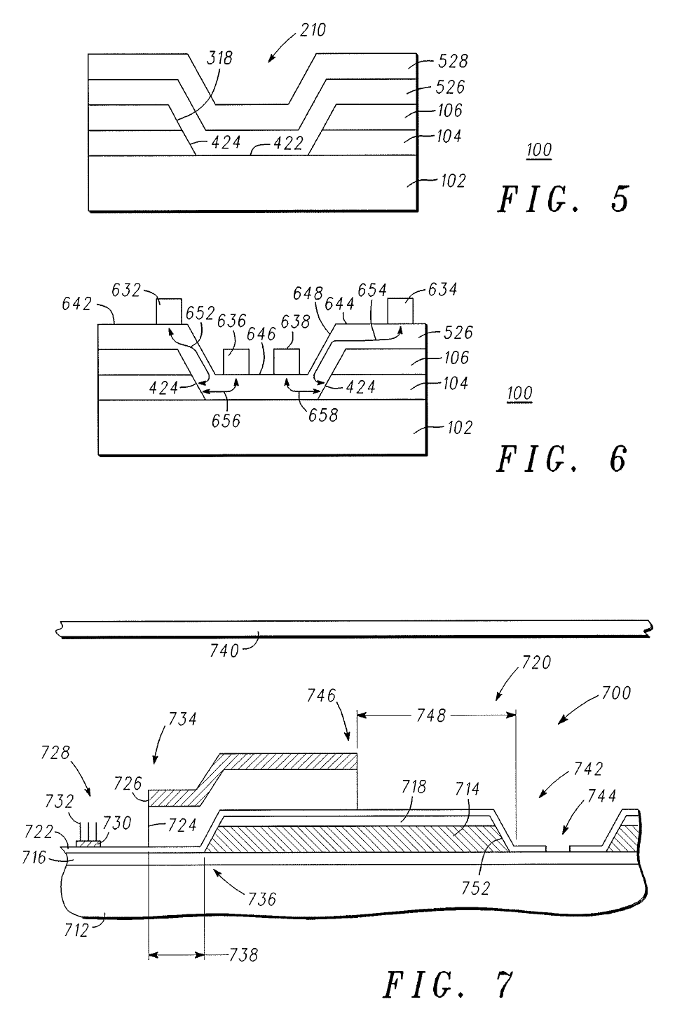

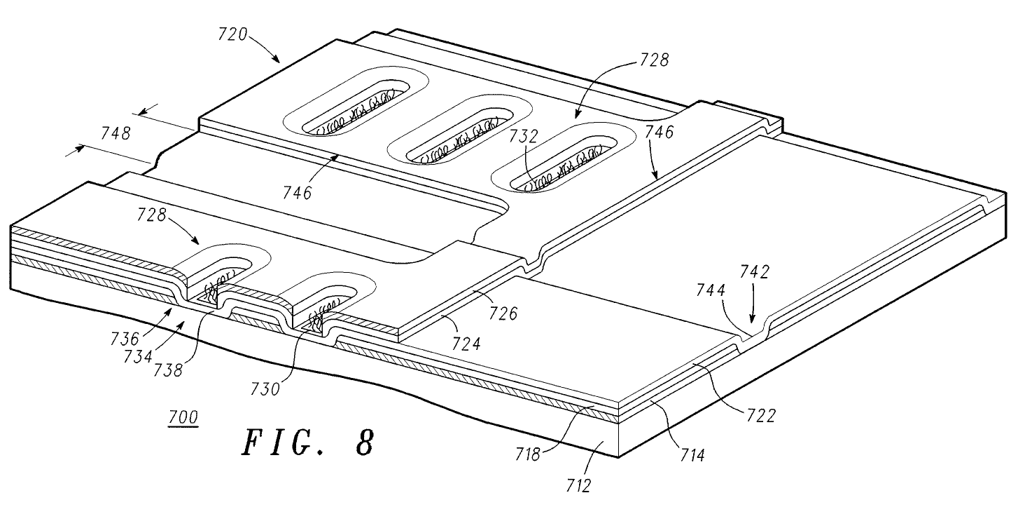

Referring to FIGS. 7 and 8, a process for forming a cathode 700 in accordance with an exemplary embodiment includes depositing a cathode metal 714 over a substrate 712. The substrate 712 comprises glass; however, alternate materials, for example, silicon, ceramic, metal, a semiconductor material, or an organic material are anticipated by this disclosure. Substrate 712 can include control electronics or other circuitry, which are not shown in this embodiment for simplicity. The cathode metal 714 preferably is molybdenum, but may comprise any metal, or group of conductors such as chrome-copper-chrome layers. An optional buried oxide or dielectric layer 716 may be formed in the top portion of the substrate 712 prior to depositing the cathode metal 714 as a diffusion barrier for contaminants and for providing a pure surface layer. The combination of this buried layer and the substrate is typically considered the ‘substrate’. In FIG. 8, the optional buried oxide layer 716 is not shown. A dielectric layer 718 is formed over the cathode metal 714. The dielectric material preferably comprises silicon oxide or silicon nitride, but may comprise any dielectric material including at least silicon dioxide, silicon oxynitride, and a spin-on glass. The thickness of this layer 718 is important. If it is too thin, it may break down at a defect site. If it is too thick, it can change the field applied to the emitters. Typical thickness range from 500 angstroms to 10 micrometers. In the preferred thin film case, the thickness lies between 2000 angstroms and one micrometer. In a thick film device, the preferred thickness for electrical integrity is approximately 4 to 10 micrometers. The cathode metal 714 and dielectric layer 718 are etched using known lithograph processes to form a structure 720.

A ballast resistor layer 722 of a semiconductor material is deposited over the dielectric layer 718 and the substrate 712. A conformal layer (e.g., dielectric layer 724) is deposited over the ballast resistor above the cathode metal 714 to provide spacing for the gate electrode 726. The gate electrode 726 comprises a conductor, for example, molybdenum or chrome-copper-chrome layers. The above layers and materials are formed by standard thin or thick film techniques known in the industry. The combination of the gate metal layer 726, dielectric layer 724, ballast resistor layer 722, dielectric layer 718, and cathode metal 714 may be referred to as a gate electrode stack. The gate electrode 726 and dielectric layer 724 define a well 728.

In accordance with known methods, the optional catalyst layer 730 is deposited on the ballast resistor 722. The catalyst 730 preferably comprises nickel, but could comprise any one of a number of other materials including cobalt, iron, and a transition metal or oxides and alloys thereof. Additionally, the catalyst 730 may be formed by any process known in the industry, e.g., evaporation, sputtering, precipitation, wet chemical impregnation, incipient wetness impregnation, adsorption, ion exchange in aqueous medium or solid state, before having the present invention applied thereto. One preferred method would be to form a relatively smooth film and subsequently etching the film to provide a rougher surface.

In FIG. 8, the exemplary embodiment shows the gate-oxide stack edge 734 closer to the emitter pad 730 than the cathode metal edge 736. Resistive material 722 lies under the gate-oxide stack edge 734 and electrically connects the electron emitter pad 730 to the cathode metal 714. The position of the gate-oxide stack edge 734 relative to the cathode metal edge 736 is important because there is now a resistive path 738 between the gate-oxide stack edge 734 and the cathode metal 736. Any defect that occurs on that edge 734 will not, with this exemplary embodiment, form a point short. In some cases, electron focusing can be improved by moving the gate-oxide stack edge 734 approximately over the top of the cathode metal step edge 736. This is most preferably done with a thick dielectric layer 718 on top of the cathode metal 714 but underlying the resistive layer 722. The ballast 722 at the edge 736 of this dielectric layer 718 then forms a lateral resistance path 738 between the gate-oxide stack edge 734 and the cathode metal 714, offering some protection against leakage currents and spurious electron emission from defects.

Carbon nanotubes 732 are then grown from the catalyst 730 in a manner known to those skilled in the art. Although only a few carbon nanotubes 732 are shown, those skilled in the art understand that any number of carbon nanotubes 732 could be formed. It should be understood that any nanotube or electron emitter having a height to radius ratio of greater than 100, for example, would function equally well with some embodiments of the present invention.

Anode plate 740 includes a solid, transparent material, for example, glass. Typically, a black matrix material (not shown) is disposed on the anode plate to define openings (not shown) representing pixels and sub-pixels containing a phosphor material (not shown) in a manner known to those in the industry. The phosphor material is cathodoluminescent and emits light upon activation by electrons, which are emitted by carbon nanotubes 732.

As used herein, carbon nanotubes include any elongated carbon structure. Preferably, the carbon nanotubes 732 are grown on a line from the catalyst 730 (in this exemplary embodiment) towards the anode 740.

Referring to FIGS. 7 and 8, the side 742 of the cathode metal 714 and dielectric layer 718 opposed to the carbon nanotubes 732 is covered by the ballast resistor 722. The ballast resistor 722 further extends onto and covers part of the buried oxide layer 716 at surface 744. As shown in FIG. 8, the ballast resistor 722 may be continuous. It is this portion of the ballast layer 722 overlying the dielectric layer 718 and the side 742 that acts as a lateral resistor for arc suppression in accordance with the exemplary embodiment. The resistive layer 722 connects to the underlying cathode metal 714 only at the sides. Consequently, the gate-oxide layer stack edge 746, which sits on the resistive layer 722, is electrically connected to the cathode metal 714 through a large span 748 of the resistive material 722. For effective prevention of spurious emission from defects, the value of this resistance needs to be larger than about 100,000 ohms. For example, this means that a defect that begins to emit one microampere of current under a gate bias of 80 volts, will experience an effective 10 volt drop. This is enough negative feedback to prevent runaway emission. More preferably, the typical resistive path would be larger than one mega-ohm in most regions, so that a small current drops nearly all of the gate voltage in the resistive layer 722, leaving no effective bias on the defect.

It is clearly preferable to have every gate-oxide stack edge 734, 746 separated by a high resistance. However, in practice, the gate metal 726 bus bar must cross the cathode metal edge 742 to proceed to the next pixel. There are several points along the gate oxide stack edge 746 where the resistive path between the gate-oxide stack edge 746 is separated from the cathode electrode 714 by only the thickness of the dielectric layer 718 on top of the cathode metal. At this location, it is often not feasible to provide sufficient resistivity. Obviously, the thicker the dielectric layer is over the cathode metal, the more protection is accomplished at these points in the device. However, the probability of having a defect in that exact location is extremely low, so the overall solution still provides good protection. Clearly, it is desirable to protect a majority of the gate-oxide edges 746 with a highly resistive path. Good protection is obtained when more than 90% of the gate-oxide stack edge 746 length is coupled to the cathode metal 714 through a resistance greater than 100K. More preferably, more than 95% of the gate-oxide stack edge 46 length is coupled to the cathode metal 714 through a resistance greater than 100K.

The exemplary embodiment, incorporating lateral resistances to the cathode metal 714 at predominantly all the gate-oxide stack edges, can be fabricated with only three mask steps. This is an important feature of a low-cost field emission device technology. An example of the fabrication sequence is as follows. The cathode metal layer 714 and the dielectric layer 718 are deposited and then patterned using the same mask step (mask 1). They are etched with a sloped sidewall etch technique in accordance with the exemplary embodiment described with reference to FIGS. 1-6.

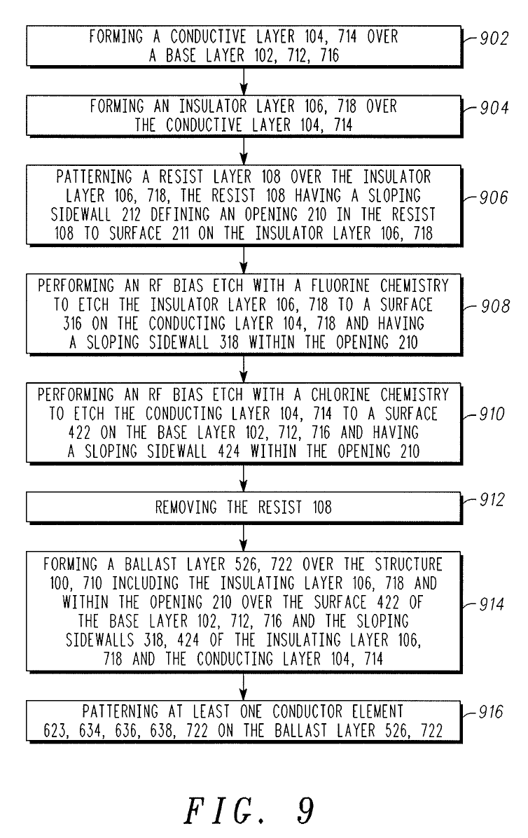

More specifically, referring to FIG. 9, a conductive layer 104, 714 is formed 902 over a base layer 102, 712, 716, e.g., a substrate, and an insulating layer 106, 718 is formed 904 over the conductive layer 104, 714. A resist 108 is patterned 906 over the insulating layer 106, 718, wherein the resist 108 has a sloping sidewall 212 defining an opening 210 to a surface 211 on the insulating layer 106, 718. The insulating layer 106, 718 is etched 908 by an RF bias etch with a fluorine chemistry to a surface 316 on the conducting layer 104, 714 and having a sloping sidewall 318 within the opening 210. The conductive layer 104, 714 is etched 910 by an RF bias etch with a chlorine chemistry to a surface 422 on the base layer 102, 712, 716 and having a sloping sidewall 424 within the opening 210. The resist 108 is removed 912, and a ballast layer 526, 722 is formed 914 over the structure 100, 710. At least one conductor element 632, 634, 636, 638, 726 is formed 916 on the ballast layer 526, 722.

The resistive layer 722 is deposited over the top. The oxide layer 724 and the gate layer 726 are deposited on the top and patterned using the same mask step (mask 2) and then etched. Finally, the nanotube catalyst layer 730 (or alternatively the nanotube-containing layer 732) is deposited and patterned using mask step 3. Consequently, the structure can be fabricated with only three mask steps. Alternatively, a fourth low resolution mask might be used to pattern the resistive layer 722 between the cathode metal bus lines 744 (mask 4). In some cases, where the expense of more mask layers can be tolerated, variations to this embodiment may exist. For example, although the dielectric layer 718 extends to the right edge of the cathode metal 714 and the ballast layer 722 extends over the dielectric layer 718 and the cathode metal 714, the dielectric layer 718 and ballast layer 722 may optionally only extend over part of the cathode metal 714.

Another benefit of this structure is that it allows laser repair of structures. In previously known devices, the act of laser repair generates unwanted metal fragments as a laser is used to evaporate metal to excise defective areas. The structure 710 described in this exemplary embodiment prevents such defects from causing point shorts, thereby enabling laser repair.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method for minimizing fabrication defects in a ballast layer contact to a conductive layer underlying an insulating layer in monolithically integrated semiconductor devices, comprising:
patterning a resist layer having a first sloping sidewall over the insulating layer;
etching with an RF biased fluorine based chemistry to form a second sloping sidewall in the insulating layer, as determined by the first sloping sidewall;
etching with an RF biased chlorine based chemistry to form a third sloping sidewall in the conductive layer, as determined by the first sloping sidewall and the second sloping sidewall; and
forming a blanket ballast layer thereover.

2. The method of claim 1 wherein the forming a sloping sidewall comprises etching with the resist layer having a 1:1 etch rate selectivity to the insulating layer.

3. The method of claim 1 wherein the forming a sloping sidewall comprises etching with the insulating layer having a 1:1 etch rate selectivity to the conductive layer.

4. The method of claim 1 further comprising forming at least two conductive elements over the ballast layer.

5. The method of claim 4 wherein the forming at least two conductive elements comprises forming at least two conductive elements wherein the resistance between each of the at least two conductive elements and the conductive layer is different.

6. The method of claim 1 wherein the etching with an RF biased fluorine based chemistry comprises forming the second sloping sidewall substantially in a plane with the first sloping sidewall.

7. The method of claim 6 wherein the etching with an RF biased chlorine based chemistry comprises forming the third sloping sidewall substantially in a plane with the second sloping sidewall.

8. A method for minimizing fabrication defects in a ballast layer contact to a conductive layer in monolithically integrated semiconductor devices, comprising:
in a structure including an insulating layer formed between a resist layer and the conducting layer, patterning a first sloping sidewall in the resist layer;
forming a second sloping sidewall in the insulating layer by etching with an RF bias and a fluorine chemistry, the second sloping sidewall defined by the first sloping sidewall;
forming a third sloping sidewall in the conducting layer by etching with an RF bias and a chlorine chemistry, the third sloping sidewall defined by the first and second sloping sidewall;
removing the resist;
blanking the remaining structure with a ballast layer; and
patterning at least one conductor element on the ballast layer.

9. The method of claim 8 wherein the forming a sloping sidewall comprises etching with the resist layer having a 1:1 etch rate selectivity to the insulating layer.

10. The method of claim 8 wherein the forming a sloping sidewall comprises etching with the insulating layer having a 1:1 etch rate selectivity to the conducting layer.

11. The method of claim 8 wherein the patterning at least one conductor element comprises forming at least two conductive elements over the ballast layer.

12. The method of claim 11 wherein the forming at least two conductive elements comprises forming at least two conductive elements wherein the resistance between each of the at least two conductive elements and the conducting layer is different.

13. The method of claim 8 wherein the forming a second sloping sidewall comprises forming the second sloping sidewall substantially in a plane with the first sloping sidewall.

14. The method of claim 13 wherein the forming a third sloping sidewall comprises forming the third sloping sidewall substantially in a plane with the second sloping sidewall.

15. A method of fabricating a monolithically integrated circuit having reduced defects in a ballast layer contact to a conductive layer, comprising:
forming the conductive layer over a base layer;
forming an insulator layer over the conductive layer;
patterning a resist layer over the insulator layer, the resist layer having a first sloping sidewall defining an opening in the resist layer to a surface on the insulator layer;
etching the insulator layer by an RF bias etch with a fluorine chemistry to a first surface on the conductive layer and having a second sloping sidewall within the opening;
etching the conductive layer by an RF bias etch with a chlorine chemistry to a second surface on the base layer and having a third sloping sidewall within the opening;
removing the resist layer;
forming a ballast layer over the insulator layer, and within the opening over the second surface of the base layer and the second and third sloping sidewalls; and
patterning at least one conductor elements on the ballast layer.

16. The method of claim 15 wherein the forming a second sloping sidewall comprises etching with the resist layer having a 1:1 etch rate selectivity to the insulator layer.

17. The method of claim 15 wherein the forming a third sloping sidewall comprises etching with the insulator layer having a 1:1 etch rate selectivity to the conductive layer.

18. The method of claim 15 further comprising forming at least two conductive elements over the ballast layer.

19. The method of claim 18 wherein the forming at least two conductive elements comprises forming at least two conductive elements wherein the resistance between each of the at least two conductive elements and the conductive layer is different.

20. The method of claim 15 wherein the forming a second sloping sidewall comprises forming the second sloping sidewall substantially in a plane with the first sloping sidewall.

21. The method of claim 20 wherein the forming a third sloping sidewall comprises forming the third sloping sidewall substantially in a plane with the second sloping sidewall.
